(19) United States
(12) Patent Application Publication
(10) Pub. No.: US 2024/0005059 A1
(43) Pub. Date: Jan. 4, 2024

(54) RISK MANAGEMENT APPARATUS, RISK MANAGEMENT METHOD, AND RISK MANAGEMENT SYSTEM

(71) Applicant: Hitachi, Ltd., Tokyo (JP)

(72) Inventors: Anjali RAJITH, Tokyo (JP); Takahiro IKEDA, Tokyo (JP)

(21) Appl. No.: 18/038,384

(22) PCT Filed: Nov. 16, 2021
(86) PCT No.: PCT/JP2021/042003

§ 371 Date: May 23, 2023

(30) Foreign Application Priority Data
Dec. 17, 2020 (JP) 2020-208963

(51) Int. Cl. G06F 30/20

(52) U.S. Cl. CPC G06F 30/20

(57) ABSTRACT

To assess a risk involving a possibility of hindering an automobile in traveling in real time. When a new risk exists, dynamically generate a new traveling scenario, a risk management apparatus specifies a risk parameter indicating a risk involved in traveling of the automobile, from sensor information acquired by a sensor unit incorporated in the automobile, determines a level of correspondence of the risk parameter with an existing traveling scenario, based on a credibility level of the risk parameter and on a correlation level of the risk parameter with the existing traveling scenario stored in a scenario database, determines a driving control action for controlling driving of the automobile, based on the level of correspondence, and generates a new traveling scenario, based on a new risk parameter of which a correlation level with the existing traveling scenario stored in the scenario database does not satisfy a given correlation level criterion.

### TECHNICAL FIELD

The present disclosure relates to a risk management apparatus, a risk management method, and a risk management system.

### BACKGROUND ART

Technologies related to automated driving have gradually come into use in recent years. Today, an improvement in automated driving functions of transportation means, particularly those of vehicles, is in great demand. Among automated driving functions, a function to ensure system safety is one of most important functions.

As an automobile travels, the surrounding environment constantly changes. Ensuring safety in this changing environment requires that a risk involving a possibility of hampering traveling of the automobile be detected in real time and that proper driving control with the risk being taken into consideration be carried out dynamically.

Various proposals for ensuring the safety of an automobile with an automated driving function have been made for years.

For example, US 2020/0148200 A1 (Patent Literature 1) discloses a technique described as: “The method includes: accessing, for a vehicle involved in a vehicle accident, at least one accident profile including information that describes data indicative of vehicle operating parameters during the accident; collecting data in real-time, from the vehicle and at least one vehicle nearby, the data describing current vehicle operation parameters for the vehicle; and comparing the data collected in real-time with the at least one accident profile to determine a probability of a vehicle collision.”

### CITATION LIST

### Patent Literature

PTL 1: US 2020/0148200 A1

### SUMMARY OF INVENTION

### Technical Problem

PTL 1 describes a means of collecting data in real time, from the vehicle and at least one vehicle close thereto, comparing the collected data with the accident profile created in advance, to determine a probability of a traffic accident, and, based on the probability, executing a preventive action for preventing the traffic accident.

According to PTL 1, however, the probability of the traffic accident is determined based on similarity between the data collected on the basis of a current traveling scenario and the existing accident profile created in advance. This approach puts an emphasis on response to a traveling scenario which is assumed in advance and for which an accident profile is created in advance while allowing a limited response to an unknown traveling scenario in which a new risk involving a possibility of hampering an automobile in traveling exists.

To further improve the safety of automated driving, therefore, a means for dynamically carrying out proper driving control with a risk being taken into consideration is needed not only for the traveling scenario which is assumed in advance and for which the accident profile is created in advance but also for the unknown traveling scenario in which the new risk involving the possibility of hampering the automobile in traveling exists.

An object of the present disclosure is to provide a risk management means that assesses, in real time, a risk involving a possibility of hampering traveling of an automobile and that when a new risk exists, dynamically generates a new traveling scenario, thereby carrying out proper driving control in any given traveling situation to improve the safety of the automobile.

### Solution to Problem

In order to solve the above problems, one of typical risk management apparatuses of the present invention includes: a sensor unit that acquires sensor information on an automobile and a surrounding environment of the automobile; a risk analysis unit that analyzes the sensor information while the automobile is traveling; a scenario management unit that manages a traveling scenario that characterizes a traveling situation of the automobile; and a scenario database that stores the traveling scenario. The risk analysis unit includes: a first parameter specifying unit that specifies a risk parameter from the sensor information acquired by the sensor unit, the risk parameter indicating a risk involved in traveling of the automobile; a credibility level calculation unit that calculates a credibility level of the risk parameter; a correlation level calculation unit that calculates a correlation level of the risk parameter with an existing traveling scenario stored in the scenario database; a scenario determination unit that determines a level of correspondence of the risk parameter with the existing traveling scenario, based on the credibility level of the risk parameter and on the correlation level of the risk parameter with the existing traveling scenario; and an action determination unit that determines a driving control action for controlling driving of the automobile, based on the level of correspondence of the risk parameter with the existing traveling scenario. Further, the scenario management unit includes: a second parameter specifying unit that when a correlation level of the risk parameter with the existing traveling scenario stored in the scenario database does not satisfy a given correlation level criterion, specifies a new risk parameter from among risk parameters, the new risk parameter being not included in the existing scenario stored in the scenario database; and a scenario generating unit that generates a new traveling scenario, based on at least the new risk parameter, the scenario generating unit adding the new traveling scenario to the scenario database.

### Advantageous Effects of Invention

According to the present disclosure, a risk management means can be provided, the risk management means assessing, in real time, a risk involving a possibility of hampering traveling of an automobile and, when a new risk exists, dynamically generating a new traveling scenario, thereby carrying out proper driving control in any given traveling situation to improve the safety of the automobile.

Problems, configurations, and effects that are not described above will be clarified by the following description of modes for carrying out the invention.

### BRIEF DESCRIPTION OF DRAWINGS

FIG. 1 depicts a computer system that carries out an embodiment of the present disclosure.

FIG. 2 depicts an example of an overall hardware configuration of a risk management system according to the embodiment of the present disclosure.

FIG. 3 depicts an example of a detailed configuration of a risk management apparatus according to the embodiment of the present disclosure.

FIG. 4 depicts an example of a data configuration of a scenario DB according to the embodiment of the present disclosure.

FIG. 5 depicts an example of a logical configuration of the risk management system according to the embodiment of the present disclosure.

FIG. 6 depicts an example of a flow of traveling scenario determination according to the embodiment of the present disclosure.

FIG. 7 depicts an example of a flow of a process in a case where, as a result of the traveling scenario determination according to the embodiment of the present disclosure, it is determined that a risk parameter included in sensor information corresponds with an unknown traveling scenario.

FIG. 8 depicts an example of a risk analysis process by a risk analysis unit according to the embodiment of the present disclosure.

FIG. 9 depicts an example in which a traveling scenario of which a correlation level with a risk parameter satisfies a correlation level criterion is specified from traveling scenarios in the scenario DB according to the embodiment of the present disclosure.

FIG. 10 depicts an example of a flow of a process by a driving management apparatus according to the embodiment of the present disclosure.

FIG. 11 depicts an example of a safety condition evaluation table indicating the effectiveness of a safety condition for each evaluation criterion, according to the embodiment of the present disclosure.

FIG. 12 depicts an example of a parameter impact level table indicating an impact level of a risk parameter for each time period, according to the embodiment of the present disclosure.

FIG. 13 depicts an example in which a new traveling scenario according to the embodiment of the present disclosure is shared with a different automobile.

### DESCRIPTION OF EMBODIMENTS

Embodiments of the present invention will hereinafter be described with reference to the drawings. It should be noted that the present invention is not limited by the embodiments. In the drawings, the same constituent elements are denoted by the same reference signs.

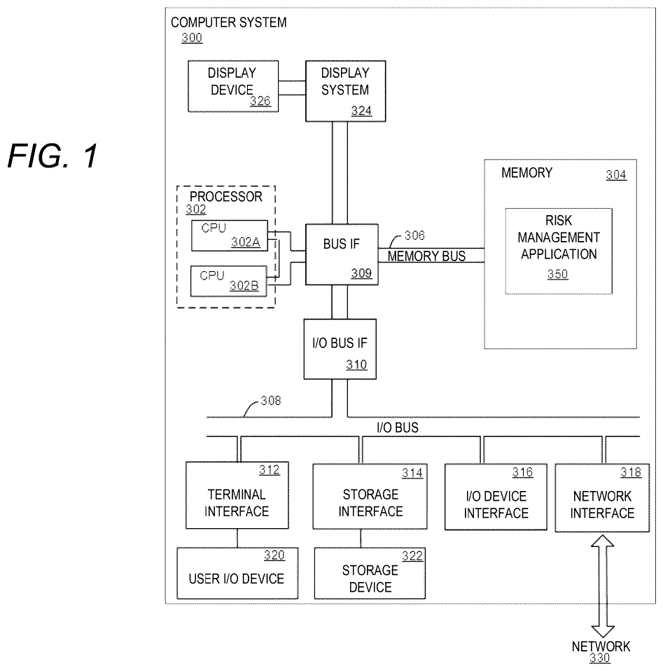

First, a computer system 300 that carries out the embodiments of the present disclosure will be described with reference to FIG. 1. Mechanisms and apparatuses for various embodiments disclosed herein may be applied to any given proper computing system. Main components of the computer system 300 include one or more processors 302, a memory 304, a terminal interface 312, a storage interface 314, an I/O (input/output) device interface 316, and a network interface 318. These components may be interconnected via a memory bus 306, an I/O bus 308, a bus interface unit 309, and an I/O bus interface unit 310.

The computer system 300 may include a single general-purpose programmable central processing unit or a plurality of general-purpose programmable central processing units (CPU) 302A and 302B, which are collectively referred to as the processors 302. In one embodiment, the computer system 300 may include a plurality of processors. In another embodiment, the computer system 300 may be a system including a single CPU. Each processor 302 executes instructions stored in the memory 304, and may include an on-board cache.

In one embodiment, the memory 304 may include a random access semiconductor memory, a storage device, or a storage medium (which is volatile or non-volatile), each of which stores data and programs. The memory 304 may store all or some of programs, modules, and data structures that exert functions described herein. For example, the memory 304 may store a risk management application 350. In one embodiment, the risk management application 350 may include instructions or descriptions for executing functions, which will be described later, on the processor 302.

In one embodiment, the risk management application 350 may be implemented on hardware, such as semiconductor devices, chips, logic gates, circuits, circuit cards, and/or other physical hardware devices, that replaces the processor-based system or works together with the processor-based system. In one embodiment, the risk management application 350 may include data different from instructions or descriptions. In one embodiment, a camera, sensor, or other data input devices (not shown) may be provided to be capable of communicating directly with the bus interface unit 309, the processor 302, or other hardware of the computer system 300.

The computer system 300 may include the bus interface unit 309 that allows the processor 302, the memory 304, a display system 324, and the I/O bus interface unit 310 to communicate with each other. The I/O bus interface unit 310 may be coupled with the I/O bus 308 for transferring/receiving data to/from various I/O units. The I/O bus interface unit 310 may communicate with a plurality of I/O interface units 312,314,316 and 318, which are known also as I/O processors (IOP) or I/O adapters (IOA), via the I/O bus 308.

The display system 324 may include a display controller, a display memory, or both of them. The display controller may provide video data, audio data, or both of them, to a display device 326. The computer system 300 may include also one or a plurality of devices, such as sensors, that are configured to collect data and provide the collected data to the processor 302.

For example, the computer system 300 may include a biometric sensor that collects heart rate data, stress level data, and the like, an environment sensor that collects humidity data, temperature data, pressure data, and the like, and a motion sensor that collects acceleration data, motion data, and the like. Other types of sensors may also be used. The display system 324 may be connected to the display device 326, which is a single display screen, a television, a tablet, or a portable device.

The I/O interface units each have a function of communicating with various storages or I/O devices. For example, the terminal interface unit 312 can be fitted with a user I/O device 320, which is a user output device, such as a video display device or a speaker television, or a user input device, such as a keyboard, a mouse, a keypad, a touchpad, a trackball, a button, a light pen, or a pointing device of a different type. By operating the user input device using a user interface, the user may input data and instructions to the user I/O device 320 and the computer system 300 and receive output data from the computer system 300. The user interface may be displayed on the display device, reproduced by a speaker, or printed out by a printer, for example, via the user I/O device 320.

The storage interface 314 can be fitted with one or a plurality of disk drives or direct-access storage devices 322 (which are usually magnetic disk drive storage devices but may be an array of disk drives or other storage devices configured to look like a single disk drive). In one embodiment, the storage device 322 may be provided as any given type of a storage device. The contents of the memory 304 may be stored in the storage device 322 and read from the storage device 322 when necessary. The I/O device interface 316 may provide an interface to other I/O devices, such as a printer and a fax machine. The network interface 318 may provide a communication path through which the computer system 300 and other devices can communicate with each other. This communication path may be, for example, a network 330.

In one embodiment, the computer system 300 may be a multi-user mainframe computer system, a single-user system, or a server computer which is a device that has no direct user interface and that receives requests from other computer systems (clients)/In other embodiments, the computer system 300 may be a desktop computer, a portable computer, a notebook computer, a tablet computer, a pocket computer, a phone, a smartphone, or any other type of proper electronic device.

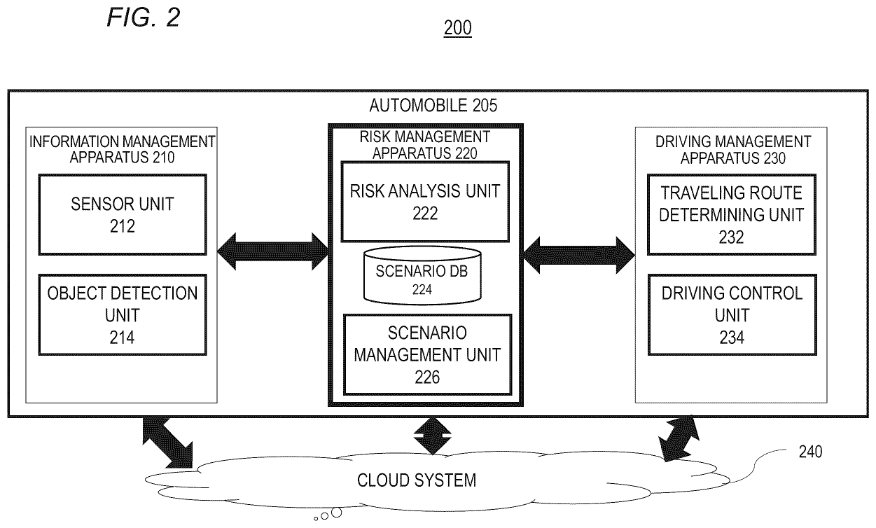

A configuration of a risk management system according to the embodiment of the present disclosure will then be described with reference to FIG. 2.

FIG. 2 depicts an example of an overall hardware configuration of a risk management system 200 according to the embodiment of the present disclosure. As shown in FIG. 2, the risk management system 200 according to the embodiment of the present disclosure mainly includes an information management apparatus 210, a risk management apparatus 220, a driving management apparatus 230, and a cloud system 240.

The information management apparatus 210, the risk management apparatus 220, and the driving management apparatus 230 that are shown in FIG. 2 may be incorporated in an automobile 205 and be connected to the cloud system 240 via a communication network (not shown in FIG. 2). The present disclosure is, however, not limited to this configuration. Some of the functions of the information management apparatus 210, the risk management apparatus 220, and the driving management apparatus 230 may be implemented by the cloud system 240 or an external computing device.

The information management apparatus 210 is an apparatus that collects and analyzes information on the automobile 205 and on the surrounding environment of the automobile 205. As shown in FIG. 2, the information management apparatus 210 includes a sensor unit 212 and an object detection unit 214.

The sensor unit 212 is a functional unit that is installed in the automobile 205 and that acquires various pieces of information on the automobile 205 and on the surrounding environment of the automobile 205. The sensor unit 212 may include, for example, a sensor configured to acquire, as sensor information, data indicating results of observation of various aspects of the automobile 205 and the surrounding environment of the automobile 205, such as image information, acoustic information, temperature information, road information, position information, movement information, atmospheric pressure information, humidity information, acceleration information, traffic information, traffic light information, disaster information, rainfall information, wind direction information, wind volume information, wind velocity information, and wind pressure information.

For example, in one embodiment, the sensor unit 212 may acquire the speed, acceleration, and current position of the automobile 205, a weather forecast, an image of the surroundings of the automobile 205, and the like.

The sensor unit 212 continuously acquires sensor information in real time, and transfers the acquired information to the object detection unit 214 and the risk management apparatus 220 and transmits the acquired information to the cloud system 240 as well.

The object detection unit 214 is a functional unit that based on sensor information acquired by the sensor unit 212, detects an object present in the surrounding environment of the automobile 205. In one embodiment, the object detection unit 214 may be, for example, a neural network (convolutional neural network) that has learned to detect, using video acquired by the sensor unit 212, a category of an object that may hinder the automobile 205 in traveling, such as a different automobile, a tree, a person, a building, or an animal.

The object detection unit 214 transfers results of object detection to the risk management apparatus 220 and transmits the results to the cloud system 240 as well.

The risk management apparatus 220 is an apparatus that assesses, in real time, a risk involving a possibility of hindering the automobile 205 in traveling, and that when a new risk exists, dynamically generates a new traveling scenario. In the present disclosure, the term “new risk” refers to a risk that does not correspond to an existing traveling scenario included in a scenario DB 224, which will be described later.

As shown in FIG. 2, the risk management apparatus 220 includes a risk analysis unit 222, the scenario DB 224, and a scenario management unit 226.

The risk analysis unit 222 is a functional unit that determines a risk involving a possibility of hindering the automobile 205 in traveling, based on sensor information acquired by the sensor unit 212 and/or on an object detection result generated by the object detection unit 214. A risk refers to an event, a situation, or an object that may possibly impair the safety or the comfortable traveling of the automobile 205. For example, the risk mentioned here is not limited to a specific risk, and may include a collision with a different automobile, rain or snow making the road slippery, fallen trees, and animals.

The detailed functions of the risk analysis unit 222 will be described later, and are therefore not described at this point.

The scenario database (hereinafter, “scenario DB”) 224 is a database that stores traveling scenarios, operational design domain (ODD) parameters, safety conditions, risk indexes, risk models, and the like that are used when an impact level of a risk is assessed quantitatively to determine a driving control action for ensuring the safety of the automobile.

A traveling scenario is information that characterizes a traveling situation of the automobile. More specifically, the traveling scenario is a data structure that represents a traveling situation at a specific time. The traveling scenario may include, for example, road information (a road type, a road shape, a road state, etc.), traffic information (a traffic volume, a speed limit, the average speed of a different automobile, etc.), the number of lanes, the presence of an object, vehicle to vehicle (V2V) information obtained through data transmission/reception to/from other automobiles, and ODD parameters.

The traveling scenario may include also information indicating a specific event or case. For example, the scenario DB 224 may include “rainy weather”, “case where a preceding vehicle brakes suddenly”, and the like, as traveling scenarios. In addition, as it will be described later, each traveling scenario stored in the scenario DB 224 may include a risk index indicating a risk that may possibly arise in the scenario. For example, the traveling scenario “case where a preceding vehicle brakes suddenly” may include a risk index indicating the risk of “colliding with the preceding vehicle”.

Furthermore, each traveling scenario may be associated with a candidate for a driving control action for ensuring the safety of the automobile 205 or a safety condition for avoiding a specific hazard in a specific traveling scenario. As it will be described later, the action determination unit can determine a proper driving control action, based on a driving control action candidate associated with a traveling scenario.

The details of the scenario DB 224 will be described later and are therefore not described at this point.

The scenario management unit 226 is a functional unit that when a new risk exists, dynamically generates a new traveling scenario to updates a traveling scenario stored in the scenario DB 224.

The details of the scenario management unit 226 will be described later and are therefore not described at this point.

The driving management apparatus 230 is an apparatus that determines a traveling route of the automobile 205 and that controls driving of the automobile 205. As shown in FIG. 2, the driving management apparatus 230 includes a traveling route determining unit 232 and a driving control unit 234.

The traveling route determining unit 232 is a functional unit that determines a traveling route of the automobile 205. The traveling route determining unit 232 may determine the traveling route of the automobile, based on a driving control action generated by the risk management apparatus 220, sensor information acquired by the sensor unit 212, and/or an operational design domain (ODD) parameter DB (not shown in FIG. 2) storing parameters that define specific operating conditions (a road type, the current position of the automobile, a speed range, environmental conditions, traffic regulations) that are set to allow the automobile to operate properly.

It should be noted that if necessary, a unit for use in an existing automated driving function may be used as the traveling route determining unit, that is, the traveling route determining unit of the present disclosure is not limited to a specific type of unit.

The driving control unit 234 is a functional unit that causes the automobile to travel along a traveling route determined by the traveling route determining unit 232. Based on the traveling route determined by the traveling route determining unit 232, the driving control unit 234 executes various controls, such as control of acceleration, deceleration, and direction changes, for allowing the automobile to safely arrive at a given destination.

The cloud system 240 is a platform that provides various services, such as computing, databases, and storages, for supporting various functions of the information management apparatus 210, the risk management apparatus 220, and the driving management apparatus 230, via a communication network, such as the Internet. The cloud system 240 may store, for example, sensor information acquired by the sensor unit 212, object detection results generated by the object detection unit 214, and a backup of data in the scenario DB 224, etc., and may undertake part of computations by the risk management apparatus 220 and the driving management apparatus 230.

According to the risk management system 200 configured in the above-described manner, a risk involving a possibility of hindering the automobile 205 in traveling can be assessed in real time and, when a new risk exists, a new traveling scenario can be generated dynamically. Hence, in any given traveling situation, proper driving control can be carried out to improve the safety of the automobile 205.

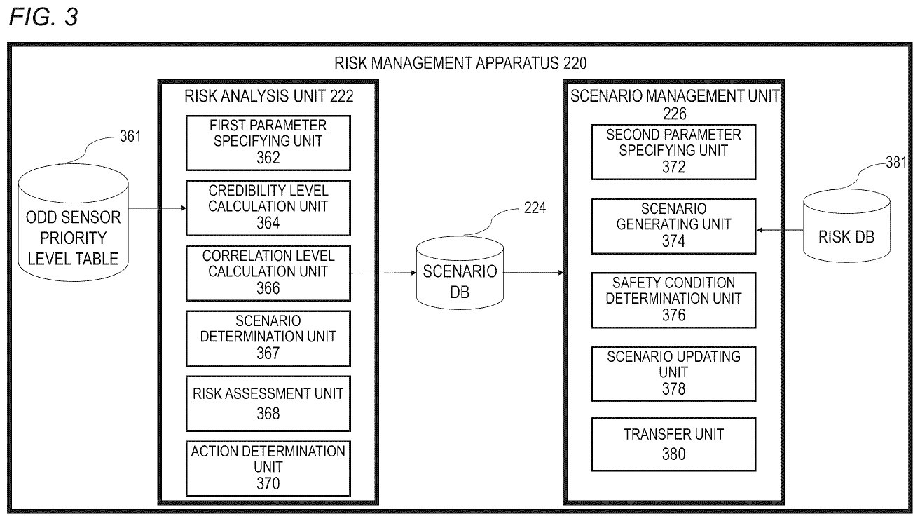

A configuration of the risk management apparatus 220 according to the embodiment of the present disclosure will then be described in detail with reference to FIG. 3.

FIG. 3 depicts an example of a detailed configuration of the risk management apparatus 220 according to the embodiment of the present disclosure. As shown in FIG. 3, the risk management apparatus 220 includes the risk analysis unit 222, the scenario DB 224, the scenario management unit 226, an ODD sensor priority level table 361, and a risk database (hereinafter, “risk DB”) 381.

As described above, the risk analysis unit 222 is the functional unit that determines a risk involving a possibility of hindering the automobile in traveling, based on sensor information acquired by the sensor unit (e.g., the sensor unit 212 shown in FIG. 2) and/or an object detection result generated by the object detection unit (e.g., the object detection unit 214 shown in FIG. 2). As shown in FIG. 3, the risk analysis unit 222 includes a first parameter specifying unit 362, a credibility level calculation unit 364, a correlation level calculation unit 366, a scenario determination unit 367, a risk assessment unit 368, and an action determination unit 370.

The first parameter specifying unit 362 is a functional unit that specifies a risk parameter indicating a risk involved in traveling of the automobile, from sensor information acquired by the sensor unit. A risk parameter is useful information for assessing a risk in a specific traveling scenario. For example, the risk parameter mentioned here may include the speed of the automobile, the type of a road (gravel road, paved road), the current time, and the distance between automobiles. The first parameter specifying unit 362 may specify a parameter with a given distribution as a risk parameter by making a statistical analysis of sensor information acquired by the sensor unit, or may specify a risk parameter by referring to a table that specifies a risk parameter in a specific traveling scenario (e.g., in a traveling scenario “rainy weather”, “tire type” may be specified as a risk parameter.).

Examples of risk parameters include, for example, Time to Collision, Safe Merging Distance, Average Velocity of Incoming lane, and Average Number of Vehicles. According to the present disclosure, however, risk parameters are not limited to these examples and any given parameters may be used as risk parameters.

The credibility level calculation unit 364 is a functional unit that calculates a credibility level indicating the certainty of a risk parameter. The credibility level mentioned here is a measure by which the certainty of the risk parameter is indicated, and may be determined based on an ODD sensor profile stored in an ODD sensor priority level table 361. This credibility level may be expressed, for example, as a numerical value ranging from 0 to 1 (a larger value indicates higher credibility level).

The ODD sensor profile is data that for each traveling scenario, specifies a priority level of sensor information. For example, in a case of a traveling scenario “night traveling”, the ODD sensor profile may give a priority level “0.4” to sensor information “RGB video information” and give a priority level “0.8” to sensor information “LIDAR video information” (which means that in a dark environment, the LIDAR video should be given higher priority over the RGB video, as more reliable information).

The correlation level calculation unit 366 is a functional unit that calculates a correlation level of a risk parameter with an existing traveling scenario stored in the scenario DB 224. The correlation level mentioned here is a measure by which a level of similarity of the risk parameter to the existing traveling scenario is indicated, and may be expressed as, for example, a numerical value ranging from 0 to 1 (a larger value indicates a higher correlation level). As it will be described later, based on this correlation level, whether a certain risk parameter corresponds with an existing traveling scenario, with an unknown traveling scenario, or with an undefined traveling scenario can be determined.

The scenario determination unit 367 is a functional unit that determines a level of correspondence of a risk parameter to an existing traveling scenario, based on a credibility level of the risk parameter calculated by the credibility level calculation unit 364 and on a correlation level of the risk parameter with the existing traveling scenario stored in the scenario DB 224. The level of correspondence mentioned here is a measure by which a level of association between the risk parameter and the existing traveling scenario is indicated. As it will be described later, this level of correspondence may indicate whether the risk parameter corresponds with an existing traveling scenario, or corresponds with an unknown traveling scenario (that is, does not correspond to the existing traveling scenario), or corresponds with an undefined traveling scenario (which means that the risk parameter is so uncertain that its level of correspondence with the existing traveling scenario is unknown).

The risk assessment unit 368 is a functional unit that analyzes a risk index in a specific traveling scenario, using a given risk model, thereby determining a hazard level of a driving control action having been determined based on the traveling scenario. The hazard level of the driving control action mentioned here is a measure by which a hazard resulting from execution of the driving control action is indicated, and may be expressed as, for example, a numerical value ranging from 0 to 1 (a larger value indicates a higher hazard level).

The action determination unit 370 is a functional unit that based on a level of correspondence of a risk parameter with an existing traveling scenario, determines a driving control action of controlling driving of the automobile. According to the present disclosure, the “driving control action” may be any given operation for controlling driving of an automobile, such as accelerating, decelerating, or changing the direction of the automobile to improve traveling safety or comfortability.

As described above, the action determination unit 370 can determine different driving control actions, depending on whether the risk parameter corresponds with an existing traveling scenario, with an unknown traveling scenario, or with an undefined traveling scenario.

As described above, the scenario management unit 226 is the functional unit that when a new risk exists, dynamically generates a new traveling scenario and updates a traveling scenario stored in the scenario DB 224. As shown in FIG. 3, the scenario management unit 226 includes a second parameter specifying unit 372, a scenario generating unit 374, a safety condition determination unit 376, a scenario updating unit 378, and a transfer unit 380.

The second parameter specifying unit 372 is a functional unit that when a correlation level of a risk parameter with an existing traveling scenario stored in the scenario DB 224 does not satisfy a given correlation level criterion, specifies a new risk parameter not included in the existing traveling scenario stored in the scenario DB 224, from among the risk parameters. The new risk parameter mentioned here refers to a risk parameter not corresponding with the existing traveling scenario. As it will be described later, a new traveling scenario can be generated using such new risk parameters.

The scenario generating unit 374 is a functional unit that generates a new traveling scenario, based on a new risk parameter specified by the second parameter specifying unit 372, traveling situation information indicating a traveling situation in which the new risk parameter has arisen, and a risk index indicating a risk that may possibly arise in the traveling situation, and adds the new traveling scenario to the scenario DB 224. When the new traveling scenario is generated, information on the risk index indicating the risk that may possibly arise in the traveling situation is stored in the risk DB 381. The risk DB 381 may include risks arose in a past traveling situation and rules set in advance to reduce the risks.

The safety condition determination unit 376 is a functional unit that determines the effectiveness of safety conditions (safety barriers) used to reduce a specific risk. These safety conditions may be, for example, measures by which a certain hazard that arises in a certain traveling scenario is reduced to ensure the safety of the automobile.

Details of a process by the safety condition determination unit 376 will be described later and are therefore not described at this point.

The scenario updating unit 378 is a functional unit that updates an existing traveling scenario stored in the scenario DB 224. The scenario updating unit 378 may update an existing traveling scenario stored in the scenario DB 224, based on, for example, an impact level of a risk parameter and on an effectiveness score of a safety condition, the effectiveness score being calculated by the safety condition determination unit 376.

The transfer unit 380 is a functional unit that when a new traveling scenario is added to the scenario DB 224, transfers the new traveling scenario to a nearby automobile existing near the automobile, via the communication network. The transfer unit 380 may transfer the new traveling scenario directly to the nearby automobile, or may transfer the new traveling scenario to the nearby automobile via, for example, a cloud server in a cloud system.

According to the risk management apparatus 220 configured in the above-described manner, a risk involving a possibility of hindering the automobile in traveling can be assessed in real time and, when a new risk exists, a new traveling scenario can be generated dynamically. Hence, in any given traveling situation, proper driving control can be carried out to improve the safety of the automobile.

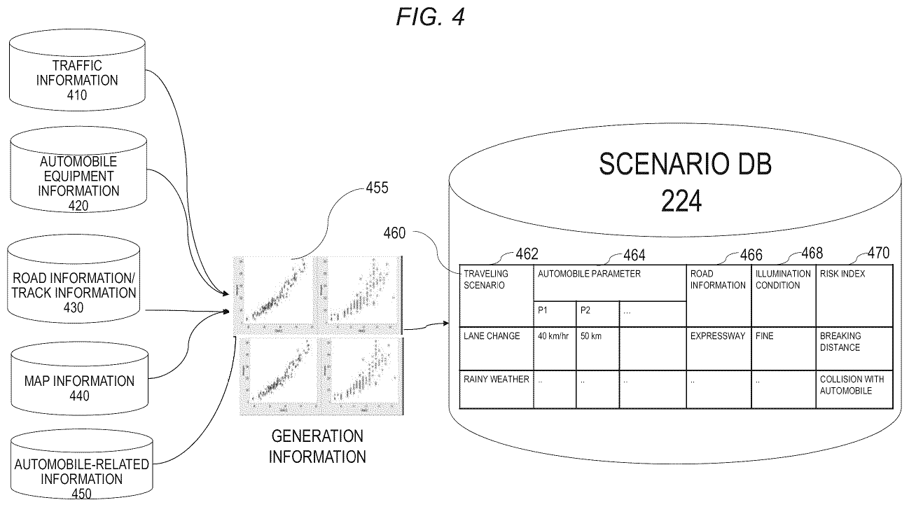

The scenario DB according to the embodiment of the present disclosure will then be described with reference to FIG. 4.

FIG. 4 depicts an example of a data configuration of the scenario DB 224 according to the embodiment of the present disclosure. As described above, the scenario DB 224 according to the embodiment of the present disclosure is a database storing traveling scenarios that are used when an impact level of a risk is assessed quantitatively to determine a driving control action for ensuring the safety of the automobile.

As shown in FIG. 4, the scenario DB 224 includes a traveling scenario management table 460 for managing traveling scenarios. The traveling scenario management table 460 may be generated based on various pieces of information acquired by the information management apparatus 210, such as traffic information 410 indicating a current traffic volume and an estimated traffic volume, automobile equipment information 420 acquired by a sensor or equipment incorporated in the automobile, traveling information 430 indicating a state of a road or a route of the automobile, map information 440 including a map showing an area where the automobile travels, and automobile-related information 450 indicating a distance relationship with a different automobile traveling near the automobile.

In one embodiment, the traveling scenario management table 460 may have various pieces of information 410, 420, 430, 440, and 450 generated by a generation process 455 based on a big data analysis and a machine learning method by a cloud system (e.g., a cloud system 240 shown in FIG. 2). By the generation process 455, a traveling scenario is generated based on the various pieces of information 410, 420, 430, 440, and 450. An existing big data analysis or machine learning method may be used as a means for generating a traveling scenario, which is not limited to a specific means.

As shown in FIG. 4, the traveling scenario management table 460 includes traveling scenarios 462, such as “lane change” and “rainy weather”, automobile parameters 464, such as the speed of the automobile or the distance to a destination, road information 466, such as “expressway”, illumination conditions 468, and risk indexes each indicating a risk that may possibly arise in the traveling scenario, such as “braking distance” and “collision with a vehicle”.

Information listed on the traveling scenario management table 460 is, however, not limited to these pieces of information. For example, in one embodiment, each traveling scenario 462 stored in the scenario DB 224 is associated with a driving control action candidate and a safety condition. In one embodiment, priority levels may be given to risk indexes, driving control action candidates, and/or safety conditions included in the traveling scenario management table 460. For example, a higher priority level may be given to a risk index corresponding with a traveling scenario with a higher hazard level, such as a crosswalk crossed by many pedestrians, a narrow road, or bad weather. In this case, the risk assessment unit and the action determination unit, which will be described later, can determine a driving control action and a hazard level of the driving control action, based on a priority level given to a risk index, a driving control action candidate, and/or a safety condition.

In one embodiment, the traveling scenario 462 in the scenario DB 224 may be expressed as tuple data, such as {Egostate₁, Egostate₂, Egostateₙ, V₁state₁, v₁state₂, {(r₁, i₁) {(rₙ, iₙ)}, hazard, {sc₁, sc₂, scₙ}}. “Egostate” is information indicating an ODD state of the automobile, “Vstate” is information indicating a state of a nearby automobile, “r” is information indicating a risk index, “i” is information indicating an impact level of a risk, and “sc” is information indicating a safety condition.

According to the scenario DB 224 configured in the above-described manner, for each of various traveling scenarios, information on a risk involving a possibility of hindering the automobile in traveling can be stored in the scenario DB 224. In addition, as it will be described later, by using a traveling scenario stored in the scenario DB 224, a driving control action for ensuring the safety of the automobile can be determined accurately in an any given situation. Furthermore, according to the present disclosure, when an unknown situation including a new risk not included in an existing traveling scenario arises, a new traveling scenario corresponding with the unknown situation is dynamically generated and is added to the scenario DB 224. As a result, in any given traveling situation, proper driving control can be carried out to improve the safety of the automobile.

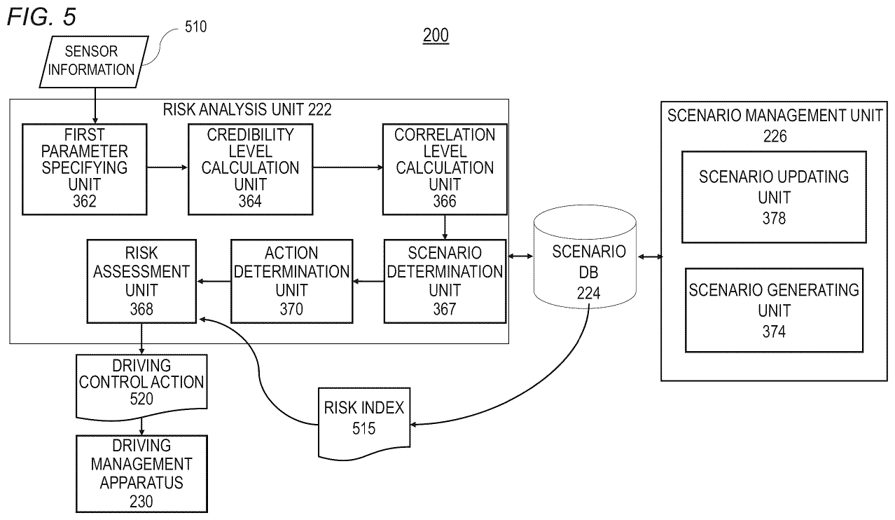

An example of a logical configuration of the risk management system according to the embodiment of the present disclosure will then be described with reference to FIG. 5.

FIG. 5 depicts an example of a logical configuration of the risk management system 200 according to the embodiment of the present disclosure. As shown in FIG. 5, the risk management system 200 mainly includes the risk analysis unit 222, the scenario DB 224, and the scenario management unit 226. The detailed configurations of the risk analysis unit 222, the scenario DB 224, and the scenario management unit 226 have been described above with reference to FIGS. 2 to 4, and are therefore omitted in further description.

In FIG. 5, for convenience in description, only the main functional units of the risk management system 200 are shown as description of some functional units is omitted.

As shown in FIG. 5, the first parameter specifying unit 362 in the risk analysis unit 222 acquires sensor information 510, which is acquired by the information management apparatus (e.g., the information management apparatus 210 shown in FIG. 2), and specifies a risk parameter indicating a risk involved in traveling of the automobile, from the sensor information 510. Subsequently, the credibility level calculation unit 364 calculates a credibility level indicating the certainty of the risk parameter specified by the first parameter specifying unit 362, based on, for example, an ODD sensor profile stored in the ODD sensor priority level table.

Subsequently, the correlation level calculation unit 366 calculates a correlation level of the risk parameter with an existing traveling scenario stored in the scenario DB 224. As described above, this correlation level is a measure by which a level of similarity of the risk parameter to the existing traveling scenario is indicated, and may be expressed as, for example, a numerical value ranging from 0 to 1 (a larger value indicates a higher correlation level). Based on this correlation level, whether a traveling scenario corresponding with the risk parameter specified by the first parameter specifying unit 362 already exists in the scenario DB 224 can be determined.

Subsequently, the scenario determination unit 367 determines a level of correspondence of the risk parameter with the existing traveling scenario, based on the credibility level of the risk parameter that is calculated by the credibility level calculation unit 364 and on the correlation level of the risk parameter with the existing traveling scenario stored in the scenario DB 224. As described above, this level of correspondence is a measure by which a level of association between the risk parameter and the existing traveling scenario is indicated. As it will be described later, this level of correspondence may indicate whether the risk parameter corresponds with an existing traveling scenario, or corresponds with an unknown traveling scenario (that is, does not correspond to the existing traveling scenario), or corresponds with an undefined traveling scenario (which means that the risk parameter is so uncertain that its level of correspondence with the existing traveling scenario is unknown).

When it is determined, based on the correlation level of the risk parameter with the existing traveling scenario stored in the scenario DB 224 and on the credibility level of the risk parameter that is calculated by the credibility level calculation unit 364, that the risk parameter corresponds with the existing traveling scenario (e.g., a first traveling scenario) stored in the scenario DB 224, the scenario determination unit 367 specifies the existing traveling scenario.

Subsequently, after the existing traveling scenario is specified based on the correlation level of the risk parameter with the existing traveling scenario stored in the scenario DB 224 and on the credibility level of the risk parameter that is calculated by the credibility level calculation unit 364, the action determination unit 370 determines a driving control action, based on the specified traveling scenario. For example, the action determination unit 370 may determine a driving control action with a performance record of its improving the safety of the automobile, the driving control action being among driving control action candidates associated with the specified traveling scenario.

Subsequently, the risk assessment unit 368 acquires a risk index 515 corresponding with the traveling scenario specified by the scenario determination unit 367, from the scenario DB 224. As described above, the risk index 515 is information indicating a risk that a specific driving control action may involve in a specific traveling scenario, and is different for each traveling scenario. When priority levels are given to risk indexes, the risk assessment unit 368 may acquire a risk index with a priority level satisfying a given priority level criterion.

Subsequently, the risk assessment unit 368 analyzes the acquired risk index 515, using the risk model corresponding with the traveling scenario, thereby determining a hazard level of the driving control action determined by the action determination unit.

More specifically, the risk assessment unit 368 can determine the hazard level of the driving control action by assessing a severity level of the risk indicated by the risk index 515 corresponding with the driving control action determined by the action determination unit, with regard to the traveling scenario specified by the scenario determination unit 367.

The risk assessment unit 368 may acquire the risk model corresponding with the existing traveling scenario from, for example, the scenario DB 224, or from a different database storing risk models for assessing the hazard level of the driving control action.

Subsequently, the risk assessment unit 368 determines whether the calculated hazard level of the driving control action satisfies a given hazard level criterion. When the calculated hazard level satisfies the given hazard level criterion, the risk assessment unit transfers the driving control action as a driving control action 520, to the driving management apparatus 230. When the calculated hazard level does not satisfy the given hazard level criterion, on the other hand, the risk assessment unit 368 transfers an instruction to change the driving control action to one that satisfies the given hazard level criterion, to the action determination unit 370.

Upon receiving the driving control action 520, the driving management apparatus 230 may execute the driving control action 520, may change the driving control action 520, or may discard the driving control action 520 and execute a different driving control action 520.

The process carried out in the case of determining that the risk parameter corresponds with the existing traveling scenario stored in the scenario DB 224 has been described above. When the risk parameter corresponds with an unknown traveling scenario (that is, does not correspond with the existing traveling scenario) or corresponds with an undefined traveling scenario, however, a different process is carried out.

More specifically, for example, when it is determined, based on the correlation level of the risk parameter with the existing traveling scenario stored in the scenario DB 224 and on the credibility level of the risk parameter that is calculated by the credibility level calculation unit 364, that the risk parameter does not correspond with the existing traveling scenario stored in the scenario DB 224, the scenario generating unit 374 generates a new traveling scenario, using a risk parameter not determined to be in correspondence with the existing traveling scenario (i.e., a new risk parameter), and stores the generated traveling scenario in the scenario DB 224.

The scenario updating unit 378 calculates impact levels of risk parameters, and then updates the existing traveling scenario stored in the scenario DB 224, using a risk parameter of which an impact level satisfies a given impact level criterion.

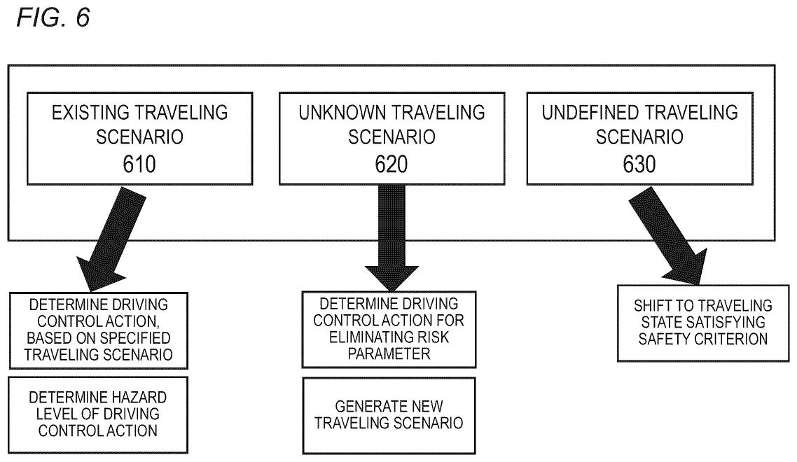

Details of scenario determination will be described later with reference to FIG. 6 and are therefore not described at this point.

According to the risk management apparatus 220 configured in the above-described manner, a risk involving a possibility of hindering the automobile in traveling can be assessed in real time and, when a new risk exists, a new traveling scenario can be generated dynamically. Hence, in any given traveling situation, proper driving control can be carried out to improve the safety of the automobile.

Traveling scenario determination according to the embodiment of the present disclosure will then be described with reference to FIG. 6.

FIG. 6 depicts an example of a flow of a scenario determination process by the scenario determination unit 367 according to the embodiment of the present disclosure. As described above, according to the present disclosure, to determine a driving control action for ensuring the safety of the automobile, it is desirable that whether a risk parameter included in sensor information corresponds with an existing traveling scenario 610 stored in the scenario DB, or with an unknown traveling scenario 620, or with an undefined traveling scenario 630 be determined.

The existing traveling scenario 610 is a traveling scenario already stored in the scenario DB. The unknown traveling scenario 620 is a traveling scenario not stored in the scenario DB. The undefined traveling scenario 630 is a traveling scenario of which a level of correspondence with a risk parameter is unknown due to the risk parameter's lack of the credibility level.

As described above, the traveling scenario determination according to the embodiment of the present disclosure is carried out, based on a credibility level calculated by the credibility level calculation unit (e.g., the credibility level calculation unit 364 shown in FIGS. 3 and 4) and on the correlation level calculation unit 366 calculated by the correlation level calculation unit 366.

More specifically, when a credibility level of a risk parameter specified by the first parameter specifying unit (e.g., the first parameter specifying unit 362 shown in FIGS. 3 and 5) satisfies the given credibility level criterion and a correlation level of the risk parameter with an existing traveling scenario (e.g., the first traveling scenario) stored in the scenario DB satisfies the given correlation level criterion, the scenario determination unit (e.g., the scenario determination unit 367 shown in FIGS. 3 and 5) determines that the risk parameter corresponds with the existing traveling scenario 610.

When it is determined that the risk parameter corresponds with the existing traveling scenario 610, the action determination unit (e.g., the action determination unit 370 shown in FIGS. 3 and 5), as described above, determines a driving control action (first driving control action), based on the existing traveling scenario 610.

Thereafter, the risk assessment unit (e.g., the risk assessment unit 368 shown in FIGS. 3 and 5) acquires a risk index for the existing traveling scenario 610, from the scenario DB (e.g., the scenario DB 224 shown in FIGS. 2 to 5), and analyzes the acquired risk index, using the risk model corresponding with the existing traveling scenario 610, thereby determining a hazard level of the driving control action determined by the action determination unit.

When the calculated hazard level satisfies the given hazard level criterion, the risk assessment unit transfers the driving control action to the driving management apparatus 230. When the calculated hazard level does not satisfy the given hazard level criterion, the risk assessment unit transfers an instruction to change the driving control action to one that satisfies the given hazard level criterion, to the action determination unit.

Now, when the credibility level of the risk parameter specified by the first parameter specifying unit satisfies the given credibility level criterion but the correlation level of the risk parameter with the existing traveling scenario stored in the scenario DB does not satisfy the given correlation level criterion, the scenario determination unit determines that the risk parameter corresponds with the unknown traveling scenario 620.

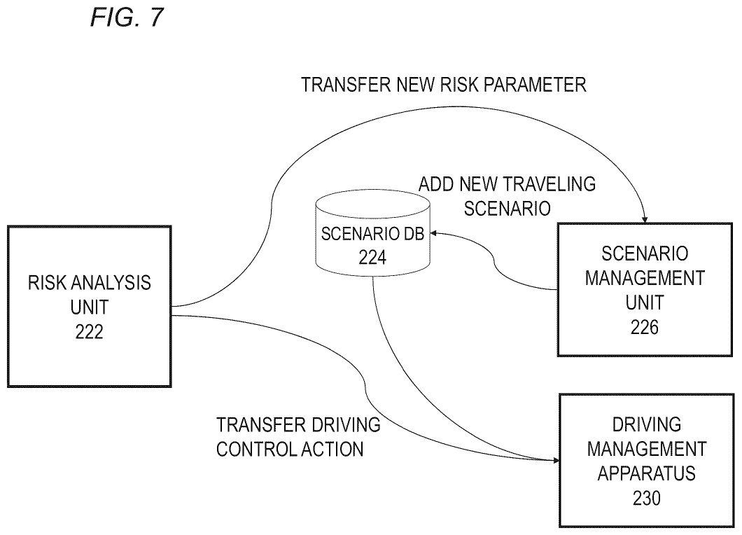

FIG. 7 depicts an example of a flow of a process in a case where, as a result of the traveling scenario determination according to the embodiment of the present disclosure, it is determined that a risk parameter included in sensor information corresponds with an unknown traveling scenario.

When it is determined that the risk parameter corresponds with the unknown traveling scenario (unknown traveling scenario 620 shown in FIG. 6), the action determination unit of the risk analysis unit 222 determines a driving control action (second driving control action) for eliminating the risk parameter, and transfers the driving control action to the driving management apparatus 230 while transferring the risk parameter as a new risk parameter, to the scenario management unit 226.

In an exemplary case of determining the driving control action, for example, when the risk parameter indicates that “the distance to a preceding vehicle is smaller than a given value”, the action determination unit may determine a driving control action of reducing the speed of the automobile so that the distance between the automobile and the preceding vehicle becomes equal to or larger than the given value.

The action determination unit may send the risk parameter directly to the scenario management unit 226 or may store the risk parameter in a staging DB (not shown) accessible to the scenario management unit 226.

Receiving the driving control action, the driving management apparatus 230 may execute the driving control action, may change the driving control action, or may discard the driving control action and execute a different driving control action.

Meanwhile, the scenario management unit 226, which has received the new risk parameter not corresponding with the existing traveling scenario, generates a new traveling scenario corresponding with the new risk parameter, and stores the generated new traveling scenario in the scenario DB 224. By accessing the scenario DB 224, the driving management apparatus 230 refers to any given traveling scenario including the new traveling scenario added to the scenario DB 224, thus being able to determine a proper driving control action.

Referring to FIG. 6 again, a case where a risk parameter corresponds with an undefined traveling scenario will then be described.

When the credibility level of the risk parameter specified by the first parameter specifying unit does not satisfy the given credibility level criterion and the correlation level of the risk parameter with the existing traveling scenario stored in the scenario DB does not satisfy the given correlation level criterion, it is determined that the risk parameter corresponds with the undefined traveling scenario 630 shown in FIG. 6.

When it is determined that the risk parameter corresponds with the undefined traveling scenario 630, the action determination unit determines a driving control action (third driving control action) of shifting to a traveling state satisfying a given safety criterion. This traveling state satisfying the safety criterion may be a stopped state or a state of minimal risk condition (MRC), which is an operation state in which some functions are rendered ineffective.

As described above, by determining whether a risk parameter included in sensor information corresponds with an existing traveling scenario stored in the scenario DB, or with an unknown traveling scenario, or with an undefined traveling scenario, a driving control action for ensuring the safety of the automobile can be determined and a new traveling scenario can be generated dynamically.

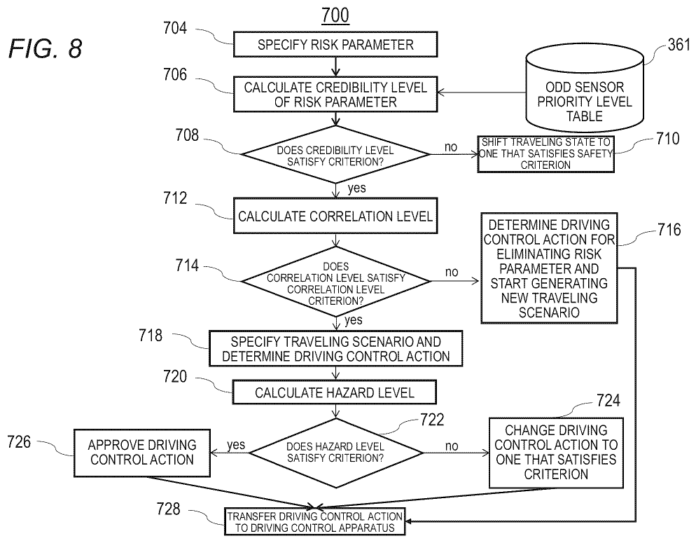

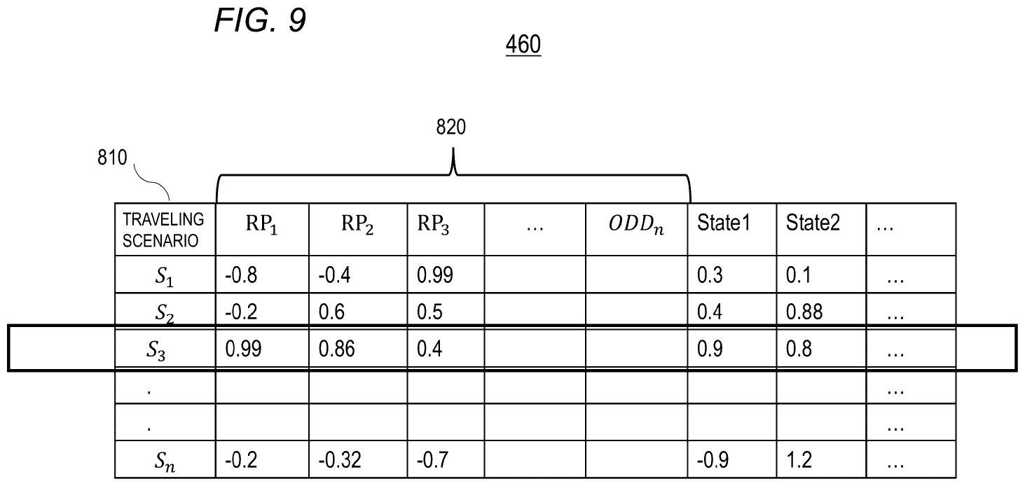

A risk analysis process by the risk analysis unit according to the embodiment of the present disclosure will then be described with reference to FIGS. 8 and 9.

FIG. 8 depicts an example of a risk analysis process 700 by the risk analysis unit according to the embodiment of the present disclosure. The risk analysis process 700 shown in FIG. 8 is a process executed by functional units making up the risk analysis unit. By the risk analysis process 700 shown in FIG. 8, a driving control action for ensuring the safety of the automobile can be determined.

First, at step 704, the first parameter specifying unit (e.g., the first parameter specifying unit 362 shown in FIG. 3) specifies a risk parameter indicating a risk involved in traveling of the automobile, from sensor information acquired by the sensor unit (e.g., the sensor unit 212 shown in FIG. 2). As described above, the first parameter specifying unit may specify a parameter with a given distribution, as the risk parameter by making a statistical analysis of the sensor information acquired by the sensor unit, or may specify the risk parameter by referring to a table that based on a given ODD state (Vehicle Position, Speed Limit, Road Type, Time of Day, Weather, Number of Lanes, etc.), specifies an important risk parameter in a specific traveling scenario (for example, in the traveling scenario “rainy weather”, a parameter “tire type” may be specified as the risk parameter.).

Examples of risk parameters include, for example, Time to Collision, Safe Merging Distance, Average Velocity of Incoming lane, and Average Number of Vehicles. According to the present disclosure, however, risk parameters are not limited to these examples and any given parameters may be used as risk parameters.

Subsequently, at step 706, the credibility level calculation unit (e.g., the credibility level calculation unit 364 shown in FIG. 3) calculates a credibility level indicating the certainty of the risk parameter. As described above, the credibility level is the measure by which the certainty of the risk parameter is indicated, and is calculated based on information on the ODD sensor profile stored in the ODD sensor priority level table 361 and on a certainty parameter R based on an object detection result given by the object detection unit. In a case where the object detection result indicates detection of all categories of objects present in the surrounding environment of the automobile (trees, buildings, automobiles, animals, etc.), the certainty parameter R is “1”. In a case where the object detection result includes an unknown object of which the category has not been detected, on the other hand, the certainty parameter R is a negative value.

As described above, the ODD sensor profile is a data structure that for each traveling scenario, indicates a priority level of sensor information and detection ranges of various sensors.

The credibility level of the risk parameter is given by the following equation 1.

Credibility level=R(w1σ₁+w2σ₂+w3σ₃+ . . . ) [Equation 1]

In this equation, w1, w2, and w3 denote weighting parameters based on respective priority levels of various sensors, the priority levels being specified in the ODD sensor profile, σ denotes a detection range of each sensor, the detection range being stored in the ODD sensor profile, and R denotes a certainty parameter based on the above object detection result.

Subsequently, at step 708, the scenario determination unit determines whether the credibility level calculated at step 706 satisfies the given credibility level criterion. This credibility level criterion is a value specifying a minimum credibility level at least needed, and may be determined based on past calculations of credibility levels or may be determined by an administrator of the risk management system 200.

When the credibility level calculated at step 706 satisfies the given credibility level criterion, the process flow proceeds to step 712. When the credibility level calculated at step 706 does not satisfy the given credibility level criterion, the process flow proceeds to step 710.

When the credibility level calculated at step 706 does not satisfy the given credibility level criterion, the scenario determination unit determines at step 710 that the risk parameter corresponds with an undefined traveling scenario. Subsequently, as described above, the action determination unit determines the driving control action (third driving control action) of shifting the state of the automobile to the traveling state satisfying the given safety criterion.

When the credibility level calculated at step 706 satisfies the given credibility level criterion, the correlation level calculation unit (e.g., the correlation level calculation unit 366 shown in FIGS. 3 and 4) calculates, at step 712, a correlation level of the risk parameter with an existing traveling scenario stored in the scenario DB. At this step, the correlation level calculation unit may use a similarity function (Euclidean distance, cosine similarity) that calculates a level of similarity of the risk parameter to the existing traveling scenario stored in the scenario DB.

At step 714, the scenario determination unit determines whether the correlation level calculated at step 712 satisfies the given correlation level criterion. This given correlation level criterion is a value specifying a minimum correlation level at least needed, and may be determined based on past calculations of correlation levels or may be determined by the administrator of the risk management system 200.

When the correlation level calculated at step 712 satisfies the given correlation level criterion, the process flow proceeds to step 718. When the correlation level calculated at step 712 does not satisfy the given correlation level criterion, the process flow proceeds to step 716.

When the correlation level calculated at step 712 does not satisfy the given correlation level criterion, the scenario determination unit determines at step 716 that the risk parameter corresponds with an unknown traveling scenario. Subsequently, as described above, the action determination unit determines the driving control action (second driving control action) for eliminating the risk parameter as the scenario generating unit starts generating a new traveling scenario. Then, the process flow proceeds to step 728.

The driving control action for eliminating the risk parameter is a driving control action of changing a traveling scenario of the automobile so that the risk parameter is not included in sensor information that will be acquired later. For example, in a case of a risk parameter “having exceeded the speed limit”, a driving control action for eliminating this risk parameter may be an action of slowing the automobile down and then letting the automobile keep traveling at normal speed. In another example, a driving control action for eliminating the risk parameter may be an action of causing the automobile to move to a different traveling zone (e.g., a different lane or the like) and then letting the automobile keep traveling at normal speed.

Subsequently, at step 718, the action determination unit (e.g., the action determination unit 370 shown in FIGS. 3 and 5) specifies a traveling scenario of which a correlation level with the risk parameter satisfies the given correlation level criterion, from among traveling scenarios in the scenario DB.

FIG. 9 depicts an example in which a traveling scenario of which a correlation level with the risk parameter satisfies the correlation level criterion is specified from among traveling scenarios in the scenario DB. As shown in FIG. 9, in the traveling scenario management table 460 stored in the scenario DB, a correlation level criterion 820 for risk parameters RP₁, RP₂, and RP₃, the correlation level criterion 820 being calculated for each traveling scenario 810, is stored. From among traveling scenarios in this traveling scenario management table 460, a traveling scenario of which a correlation level with the risk parameters RP₁, RP₂, and RP₃ satisfies the given correlation level criterion (e.g., a traveling scenario having the highest correlation level) is specified. For example, as shown in FIG. 9, a traveling scenario S₃ has the highest total correlation level with the risk parameters RP₁, RP₂, and RP₃, and is therefore specified.

After the traveling scenario of which the correlation level with the risk parameter satisfies the given correlation level criterion is specified, the action determination unit determines a driving control action, based on the specified traveling scenario. In one embodiment, the action determination unit may determine a driving control action with a performance record of its improving the safety of the automobile, from among driving control action candidates associated with the specified traveling scenario.

Subsequently, at step 720, the risk assessment unit (e.g., the risk assessment unit 368 shown in FIGS. 3 and 5) acquires a risk index for the traveling scenario specified at step 718, from the scenario DB, and analyzes the acquired risk index using the risk model corresponding with the traveling scenario, thereby determining a hazard level of the driving control action determined at step 718. When priority levels are given to risk indexes, the risk assessment unit 368 may acquire a risk index with a priority level satisfying a given priority level criterion.

For example, as a result of analyzing the acquired risk index using the risk model corresponding with the traveling scenario, the risk assessment unit gives a severity level “0.2” to a risk index “automobile slips to become unstable in steering” and gives a severity level “0.3” to a risk index “collides with a trailing vehicle”, with regard to a driving control action “hit the break” in the traveling scenario “rainy weather”, and then may determine a hazard level of the driving control action, based on these risk indexes. For example, the risk assessment unit may use an average of the severity levels calculated respectively for the risk indexes, as the hazard level of the driving control action. In this case, the hazard level of the driving control action is calculated at “0.25”.

Subsequently, at step 722, the risk assessment unit determines whether the hazard level calculated at step 720 satisfies a given hazard level criterion. This hazard level criterion is a value that specifies a hazard level within an allowable range, and may be set by, for example, the administrator of the risk management system. For example, when the given hazard level criterion is “0.3 or less”, it is determined that the above driving control action of which the hazard level is “0.25” satisfies the given hazard level criterion.

When the hazard level calculated at step 720 satisfies the given hazard level criterion, the process flow proceeds to step 726. When the hazard level calculated at step 720 does not satisfy the given hazard level criterion, the process flow proceeds to step 724.

When the hazard level calculated at step 720 does not satisfy the given hazard level criterion, the action determination unit, at step 724, changes the driving control action to one that satisfies the given hazard level criterion. For example, the action determination unit may change automobile operation parameters specified by the driving control action, such as a speed, an acceleration, and the distance to a different vehicle, to safer parameter values so that the driving control action satisfies the given hazard level criterion.

When the hazard level calculated at step 720 satisfies the given hazard level criterion, the driving control action is approved at step 726.

Subsequently, at step 728, the action determination unit transfers the driving control action approved at step 726 or the driving control action determined at step 716, to the driving management apparatus. Then, the driving management apparatus may execute the driving control action, may change the driving control action, or may discard the driving control action and execute a different driving control action.

According to the risk analysis process 700 described above, a risk involving a possibility of hindering the automobile in traveling can be assessed in real time and, when a new risk exists, a new traveling scenario can be generated dynamically. Hence, in any given traveling situation, proper driving control can be carried out to improve the safety of the automobile.

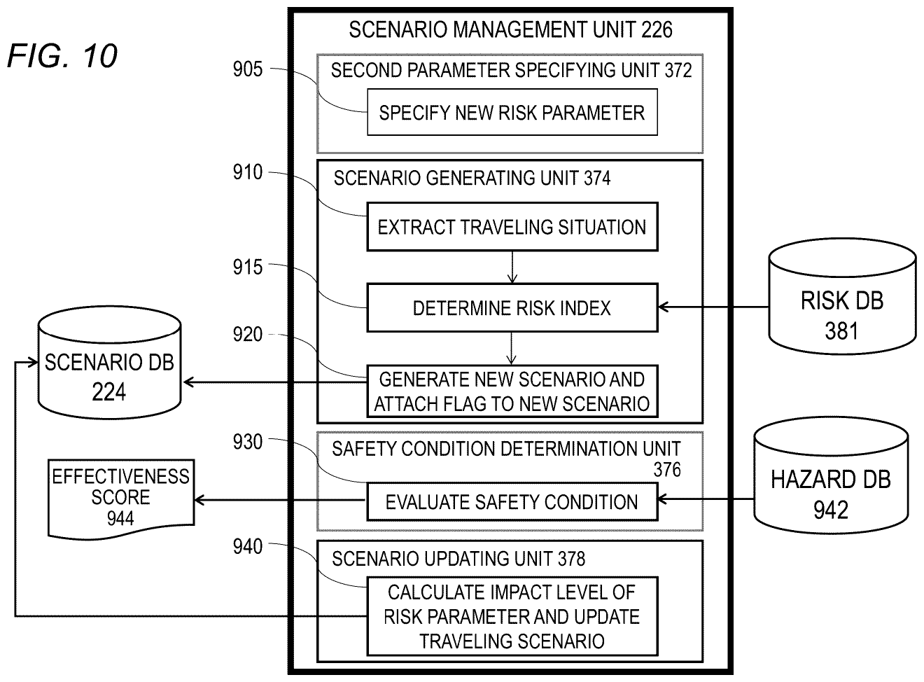

A flow of process by the driving management apparatus according to the embodiment of the present disclosure will then be described with reference to FIG. 10.

FIG. 10 depicts an example of a flow of a process by the driving management apparatus 230 according to the embodiment of the present disclosure. As described above, the driving management apparatus 230 according to the embodiment of the present disclosure is a functional unit that when a new risk exists, dynamically generates a new traveling scenario to continuously update a traveling scenario stored in the scenario DB 224. As shown in FIG. 10, the driving management apparatus 230 includes the second parameter specifying unit 372, the scenario generating unit 374, the safety condition determination unit 376, and the scenario updating unit 378.

For convenience in description, FIG. 10 show only the main functions of the scenario management unit 226, and description of some functional units thereof is omitted.

A flow of processes of respective functional units will hereinafter be described.

First, at step 905, the second parameter specifying unit 372 specifies a risk parameter not included in an existing scenario stored in the scenario DB 224, as a new risk parameter, the risk parameter being specified from among risk parameters specified by the first parameter specifying unit of the risk analysis unit (e.g., the first parameter specifying unit 362 of the risk analysis unit 222 shown in FIG. 3).

Subsequently, at step 910, the scenario generating unit 374 analyzes sensor information acquired by the sensor unit (e.g., the sensor unit 212 shown in FIG. 2), thereby extracting traveling situation information indicating a traveling situation in which the new risk parameter specified at step 905 is measured. For example, in a case where “average number of vehicles” is specified as the new risk parameter, the scenario generating unit 374 may extract traveling situation information “traveling on an expressway in a big city” by analyzing the sensor information. In this manner, a traveling situation in which the new risk parameter has arisen can be determined.

Subsequently, at step 915, the scenario generating unit 374 refers to a risk DB 381, thereby determining the risk index corresponding with the traveling situation extracted at step 910. The risk DB 381 may include risks arose in past traveling situations and rules set in advance to reduce the risks. The risk DB 381 may be a database that is created in advance, based on, for example, past traveling situation information or experts' knowledge.

For example, in the case of the traveling situation “traveling on an expressway in a big city”, the scenario generating unit 374 may determine “collide with a pedestrian”, “traffic jam”, and the like, as risk indexes by referring to the risk DB 381.

The risk indexes determined at this step may be associated respectively with weights indicating the importance of the risk indexes.

Subsequently, at step 920, the scenario generating unit 374 generates a new traveling scenario, based on the new risk parameter specified at step 905, the traveling situation extracted at step 910, and the risk index determined at step 915, adds the generated new traveling scenario to the scenario DB224, and attaches a flag to the new traveling scenario. More specifically, using a given API or library, the scenario generating unit 374 registers specified parameters (risk parameter, ODD parameter), a traveling situation in which these parameters arose, and the risk index corresponding with the traveling situation, with the scenario DB224, as a new traveling scenario.

It should be noted that in some cases, further safety verification should preferably be carried out before a driving control action for controlling driving of the automobile is determined based on the new traveling scenario. At the point of generation of the new traveling scenario, therefore, a flag for recommending further safety verification is attached to the new traveling scenario. Thereafter, the scenario management unit 226 may delete this flag after verifying the safety of the new traveling scenario by the user's confirmation, updating of safety conditions, or the like.

In one embodiment, when a new traveling scenario is added to the scenario management unit 226, a transfer unit (not shown in FIG. 10) of the scenario management unit 226 may transfer the new traveling scenario to an automobile traveling nearby via a communication network, such as the Internet, to share the new traveling scenario with the automobile.

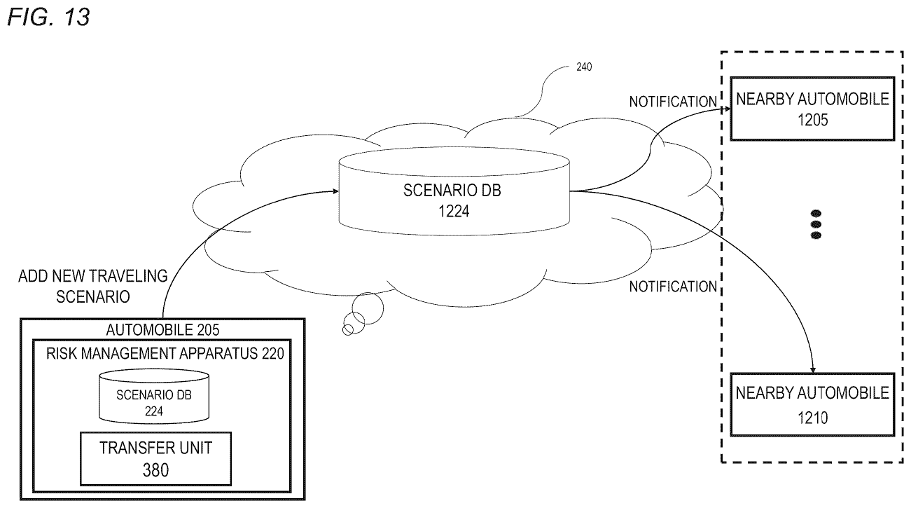

Details of the case of sharing a new traveling scenario with an automobile traveling nearby will be described later with reference to FIG. 13, and are therefore not described at this point.

As described above, the scenario management unit 226 includes the safety condition determination unit 376 that determines the effectiveness of a safety condition used to reduce a specific risk. A safety condition is, for example, a measure to reduce a specific hazard arising in a specific traveling scenario and secure the safety of the automobile, and may be stored in the scenario DB 224.

At step 930, the safety condition determination unit 376 evaluates a safety condition corresponding with a hazard that may possibly arise in a specific traveling scenario, based on a given evaluation criterion, thereby calculating an effectiveness score indicating the effectiveness of each safety condition.

More specifically, the safety condition determination unit 376 acquires a safety condition corresponding with a hazard that may possibly arise in a specific traveling scenario, from a hazard database (hereinafter, “hazard DB”) 945. The hazard DB (hazard database) 945 is a database that stores, for each traveling scenario, a hazard that may possibly arise in the traveling scenario and a safety condition for reducing a hazard level resulting from the hazard. For example, the hazard DB 945 may include, for the traveling scenario “rainy weather”, a hazard “collision caused by the automobile's slipping” and a safety condition “increase the distance to a vehicle nearby”.

After acquiring a safety condition corresponding with a specific hazard, the safety condition determination unit 376 evaluates the acquired safety condition, based on the given evaluation criterion, thereby calculating an effectiveness score 944 indicating the effectiveness of the safety condition. The evaluation criterion is a parameter selected to evaluate the effectiveness of the safety condition. For example, the evaluation criterion may include the frequency (fₕ) of occurrence of a hazard corresponding with a target safety condition, a severity level (sₕ) of the hazard corresponding with the target safety condition, the frequency (fₐ) of the target safety condition's becoming a risk parameter, the effect (eᵣ) of avoiding the hazard corresponding with the target safety condition, and effectiveness (Odd₁) for detecting ODD parameters, such as rainfall, snowing, and illuminance. The evaluation criterion according to the present disclosure, however, is not limited to these parameters but may include any types of parameters for evaluating the effectiveness of safety measures.

These evaluation criteria may be associated with weights indicating the importance of the evaluation criteria.

In one embodiment, the safety condition determination unit 376 may calculate an effectiveness score indicating the effectiveness of each safety condition for each evaluation criterion. The score indicating the effectiveness of the safety condition is given by the following equation 2.

Effectiveness score=f(λ)*wₙ [Equation 2]

In this equation, f(λ) denotes a function representing the frequency of use of a specific safety condition within a given time, and wₙ denotes a weight added to an evaluation criterion.

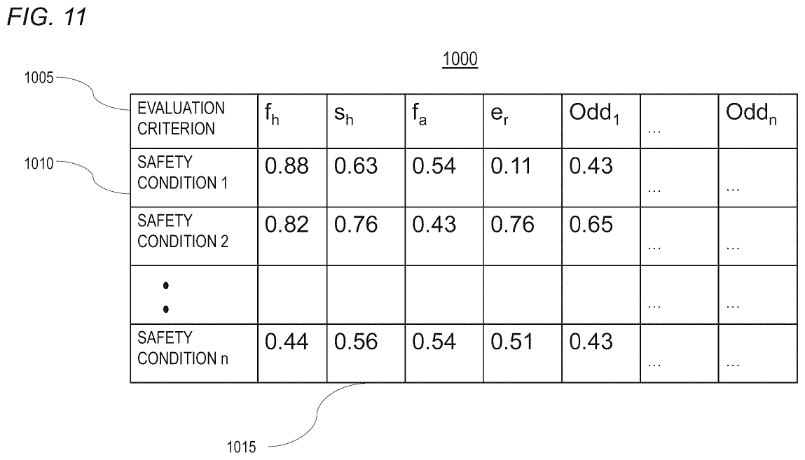

FIG. 11 depicts an example of a safety condition evaluation table 1000 indicating the effectiveness of a safety condition for each evaluation criterion, according to the embodiment of the present disclosure. As shown in FIG. 11, the safety condition evaluation table 1000 indicates, for each evaluation criterion 1005, an effectiveness score 1015 of each of safety conditions 1010 consisting of a given number of safety conditions, i.e., a safety condition 1, a safety condition 2 . . . a safety condition n.

After calculating the effectiveness score of each safety condition, the safety condition determination unit 376 outputs the calculated effectiveness score 944 of each safety condition. In one embodiment, the safety condition determination unit 376 may transfer the effectiveness score 944 to the scenario updating unit 378.

According to the safety condition evaluation described above, the effectiveness of a safety condition used to reduce a specific risk can be evaluated. As a result, for each traveling scenario, the effect of each safety condition for reducing a hazard in the traveling scenario can be understood. Hence, by deleting or changing a safety condition with low effectiveness and adding a safety condition with higher effectiveness, the traveling safety of the automobile can be ensured.

As described above, the scenario management unit 226 includes the scenario updating unit 378 that updates an existing traveling scenario stored in the scenario DB 224.

At step 940 shown in FIG. 10, for example, the scenario updating unit 378 may calculate an impact level of a risk parameter specified by the first parameter specifying unit and may update an existing traveling scenario stored in the scenario DB 224, based on the impact level of the risk parameter and an effectiveness score of a safety condition calculated by the safety condition determination unit 376.

More specifically, at step 940, the scenario updating unit 378 analyzes a risk parameter specified by the first parameter specifying unit, based on operation conditions, such as the speed, acceleration, and current position of the automobile and number of automobiles traveling nearby, thereby calculating an impact level of the risk parameter for each time period. The impact level mentioned here is a measure by which a possibility of the risk parameter's leading to a traffic accident is indicated, and may be expressed as a category of “safe”, “hazardous”, or “high possibility of a traffic accident”, or may be expressed as a numerical value ranging from 0 to 1 (a larger value indicates a higher impact level, that is, a higher possibility of a traffic accident).

In one embodiment, the scenario updating unit 378 may calculate the impact level of the risk parameter for each time period, by using a neural network, such as a Multilayer Perceptron (MLP) having learned past risk parameters.

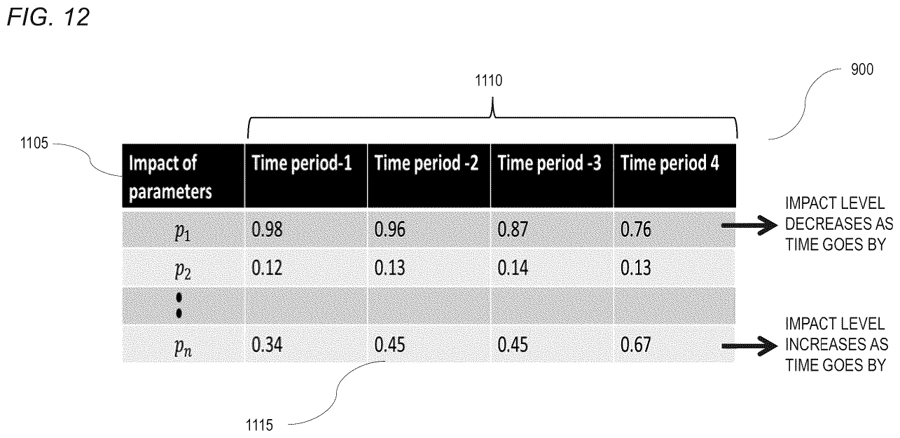

FIG. 12 depicts an example of a parameter impact level table 1100 indicating an impact level of a risk parameter for each time period, according to the embodiment of the present disclosure. As shown in FIG. 12, the parameter impact level table 1100 indicates, for each time period 1110, an impact level 1115 of each of risk parameters 1105 consisting of risk parameters p1, p2 . . . pn.

In this manner, variations in an impact level of a specific risk parameter can be determined along a time-sequence flow.

After calculating the impact level of the risk parameter, the scenario updating unit 378 updates an existing traveling scenario stored in the scenario DB 224, based on the calculated impact level of the risk parameter and on the effectiveness score 944 indicating the effectiveness of the safety condition calculated at step 930. Based on the effectiveness score 944, the scenario updating unit 378 may adjust a safety condition for a traveling scenario including a risk parameter of which an impact level satisfies the given impact level criterion. For example, after specifying a traveling scenario including a risk parameter of which an impact level satisfies the given impact level criterion, the scenario updating unit 378 may delete a safety condition with a low effectiveness score from safety conditions corresponding with the traveling scenario or change a safety condition to improve the effectiveness score. Updating of a traveling scenario is not limited to the above process, and may include addition, deletion, or change of any given parameter.

Thus, existing traveling scenarios stored in the scenario DB 224 are constantly kept in their latest state. As a result, in any given traveling situation, proper driving control can be carried out to improve the safety of the automobile.

An example in which a new traveling scenario according to the embodiment of the present disclosure is shared with a different automobile will then be described with reference to FIG. 13.

FIG. 13 depicts an example in which a new traveling scenario according to the embodiment of the present disclosure is shared with a different automobile. As shown in FIG. 13, when a new traveling scenario is generated by the scenario generating unit (e.g., the scenario generating unit 374 shown in FIG. 3) and is added to the scenario DB 224 as a local DB incorporated in an automobile 205, the transfer unit 380 in the risk management apparatus 220 synchronizes the scenario DB 224, i.e., local DB with a scenario DB 1224 in a cloud system 240. As a result, the new traveling scenario generated on the automobile side is added to the scenario DB 1224 in the cloud system 240 as well.

At this time, the scenario DB 1224 in the cloud system 240 may send a notification including information on the newly added traveling scenario, to nearby automobiles 1205 and 1210, which are traveling near the automobile 205. The nearby automobiles 1205 and 1210 may be, for example, automobiles existing within a given range of distance to the automobile 205 (existing within an area 500 meters or less distant or 1 km or less distant to the automobile 205).

Thus, the nearby automobiles 1205 and 1210 may register the new traveling scenario received from the cloud system 240 with their local scenario DBs, and may determine a driving control action for ensuring traveling safety, based on the new traveling scenario.

In this manner, sharing the traveling scenario generated by one automobile with other nearby automobiles makes it possible to efficiently determine a risk that may possibly arise in a bad weather condition, such as rainy weather or heavy snowing, or a driving control action for reducing such a risk.

FIG. 13 shows an exemplary case where the notification including the information on the newly added traveling scenario is sent to two nearby automobiles. The present disclosure is, however, not limited to such an exemplary case, and this notification may be sent to any number of automobiles.

FIG. 13 shows an exemplary case where the notification including the information on the new traveling scenario is sent from the automobile 205 to the nearby automobiles 1205 and 1210 via the scenario DB 1224 of the cloud system 240. The present disclosure is, however, not limited to such an exemplary case, and the transfer unit 380 of the automobile 205 may send the notification including the information on the new traveling scenario directly to the nearby automobiles 1205 and 1210 not via the cloud system 240 but through a communication network, such as a LAN.

According to the risk management apparatus, the risk management method, and the risk management system that have been described above, a risk involving a possibility of hindering the automobile in traveling is assessed in real time and, when a new risk exists, a new traveling scenario is generated dynamically. Hence, in any given traveling situation, proper driving control can be carried out to improve the safety of the automobile. In the above, aspects of the present disclosure have been described for an exemplary case where the main purpose is to improve the safety of the automobile. The present disclosure is, however, not limited to such an exemplary case, and may be applied also to a case where in addition to the safety of the automobile, the comfortability of a passenger of the automobile is improved.

While the embodiment of the present invention has been described above, the present invention is not limited to the above-described embodiment and may be modified into various forms within a range not departing from the subject of the present invention.

### REFERENCE SIGNS LIST

200 risk management system
205 automobile
210 information management apparatus
212 sensor unit
214 object detection unit
220 risk management apparatus
222 risk analysis unit
224 scenario DB
226 scenario management unit
230 driving management apparatus
232 traveling route determining unit
234 driving control unit
240 cloud system

1. A risk management apparatus that manages a risk involved in traveling of an automobile, the risk management apparatus comprising:
a sensor unit that acquires sensor information on the automobile and on a surrounding environment of the automobile;
a risk analysis unit that analyzes the sensor information while the automobile is traveling;
a scenario management unit that manages a traveling scenario that characterizes a traveling situation of the automobile; and
a scenario database that stores the traveling scenario,
wherein
the risk analysis unit includes:
a first parameter specifying unit that specifies a risk parameter from the sensor information acquired by the sensor unit, the risk parameter indicating a risk involved in traveling of the automobile;
a credibility level calculation unit that calculates a credibility level of the risk parameter;
a correlation level calculation unit that calculates a correlation level of the risk parameter with an existing traveling scenario stored in the scenario database;
a scenario determination unit that determines a level of correspondence of the risk parameter with the existing traveling scenario, based on the credibility level of the risk parameter and on the correlation level of the risk parameter with the existing traveling scenario; and
an action determination unit that determines a driving control action for controlling driving of the automobile, based on the level of correspondence of the risk parameter with the existing traveling scenario, and
the scenario management unit includes:
a second parameter specifying unit that when the correlation level of the risk parameter with the existing traveling scenario stored in the scenario database does not satisfy a given correlation level criterion, specifies a new risk parameter from among risk parameters, the new risk parameter being not included in the existing scenario stored in the scenario database; and
a scenario generating unit that generates a new traveling scenario, based on at least the new risk parameter, the scenario generating unit adding the new traveling scenario to the scenario database.

2. The risk management apparatus according to claim 1,
wherein
when a credibility level of the risk parameter satisfies a given credibility level criterion and a correlation level of the risk parameter with a first traveling scenario stored in the scenario database satisfies a given correlation level criterion, the scenario determination unit determines that the risk parameter corresponds with the first traveling scenario, and
the action determination unit determines a first driving control action of controlling driving of the automobile, based on the first traveling scenario.

3. The risk management apparatus according to claim 1,
wherein
when a credibility level of the risk parameter satisfies a given credibility level criterion but a correlation level of the risk parameter with the existing traveling scenario stored in the scenario database does not satisfy a given correlation level criterion, the scenario determination unit determines that the risk parameter corresponds with an unknown traveling scenario, and
the action determination unit determines a second driving control action of eliminating the risk parameter.

4. The risk management apparatus according to claim 1,
wherein
when a credibility level of the risk parameter does not satisfy a given credibility level criterion and a correlation level of the risk parameter with the existing traveling scenario stored in the scenario database does not satisfy a given correlation level criterion, the scenario determination unit determines that the risk parameter corresponds with an undefined traveling scenario, and
the action determination unit determines a third driving control action of controlling driving of the automobile in such a way as to put the automobile in a traveling state that satisfies a given safety criterion.

5. The risk management apparatus according to claim 1, wherein the scenario management unit further includes a safety condition determination unit that based on a given evaluation criterion, evaluates a safety condition indicating a measure to take in a case where a specific hazard arises in a specific traveling scenario, thereby calculating an effectiveness score indicating effectiveness of the safety condition.

6. The risk management apparatus according to claim 5, wherein the given evaluation criterion includes a frequency of occurrence of a hazard corresponding with the safety condition, a severity level of the hazard corresponding with the safety condition, a frequency of the safety condition's becoming a risk parameter, an effect of avoiding the hazard corresponding with the safety condition, and a specific ODD parameter.

7. The risk management apparatus according to claim 5, wherein the scenario management unit further includes a scenario updating unit that calculates an impact level of the risk parameter on the existing traveling scenario stored in the scenario database and that, when the impact level satisfies a given impact level criterion, updates the existing traveling scenario, based on the risk parameter.

8. The risk management apparatus according to claim 7, wherein when the effectiveness score indicating effectiveness of the safety condition satisfies a given effectiveness criterion, the scenario updating unit updates the existing traveling scenario, based on the effectiveness score.

9. The risk management apparatus according to claim 1, wherein the scenario management unit further includes a transfer unit that when the new traveling scenario is added to the scenario database, transfers the new traveling scenario to a nearby automobile existing near the automobile, via a communication network.

10. A risk management method of managing a risk involved in traveling of an automobile, the risk management method comprising the steps of:
specifying a risk parameter indicating a risk involved in traveling of the automobile, from sensor information on the automobile and on a surrounding environment of the automobile, the sensor information being acquired by a sensor unit incorporated in the automobile;
calculating a credibility level of the risk parameter;
calculating a correlation level of the risk parameter with an existing traveling scenario stored in a scenario database that manages traveling scenarios characterizing a traveling situation of the automobile;
determining a level of correspondence of the risk parameter with the existing traveling scenario, based on the credibility level of the risk parameter and on the correlation level of the risk parameter with the existing traveling scenario;
determining a driving control action for controlling driving of the automobile, based on the level of correspondence of the risk parameter with the existing traveling scenario;
specifying a new risk parameter from among risk parameters, the new risk parameter being not included in the existing scenario stored in the scenario database, when the correlation level of the risk parameter with the existing traveling scenario stored in the scenario database does not satisfy a given correlation level criterion; and
generating a new traveling scenario, based on the new risk parameter, traveling situation information indicating a traveling situation in which the new risk parameter has arisen, and a risk index indicating a risk that may possibly arise in the traveling situation, and adding the new traveling scenario to the scenario database.

11. A risk management system that manages a risk involved in traveling of an automobile, the risk management system comprising:
an automobile;
a nearby automobile existing near the automobile; and
a cloud server,
wherein
the automobile includes:
a sensor unit that acquires sensor information on the automobile and on a surrounding environment of the automobile;
a risk analysis unit that analyzes the sensor information while the automobile is traveling;
a scenario management unit that manages a traveling scenario that characterizes a traveling situation of the automobile; and
a scenario database that stores the traveling scenario,
the risk analysis unit includes:
a first parameter specifying unit that specifies a risk parameter from the sensor information acquired by the sensor unit, the risk parameter indicating a risk involved in traveling of the automobile;
a credibility level calculation unit that calculates a credibility level of the risk parameter;
a correlation level calculation unit that calculates a correlation level of the risk parameter with an existing traveling scenario stored in the scenario database;
a scenario determination unit that determines a level of correspondence of the risk parameter with the existing traveling scenario, based on the credibility level of the risk parameter and on the correlation level of the risk parameter with the existing traveling scenario; and
an action determination unit that determines a driving control action for controlling driving of the automobile, based on the level of correspondence of the risk parameter with the existing traveling scenario, and
the scenario management unit includes:
a second parameter specifying unit that when the correlation level of the risk parameter with the existing traveling scenario stored in the scenario database does not satisfy a given correlation level criterion, specifies a new risk parameter from among risk parameters, the new risk parameter being not included in the existing scenario stored in the scenario database;
a scenario generating unit that generates a new traveling scenario, based on the new risk parameter, traveling situation information indicating a traveling situation in which the new risk parameter has arisen, and a risk index indicating a risk that may possibly arise in the traveling situation, the scenario generating unit adding the new traveling scenario to the scenario database; and
a transfer unit that when the new traveling scenario is added to the scenario database, transfers the new traveling scenario to the nearby automobile via the cloud server.
